(19) United States
(12) Patent Application Publication
(10) Pub. No.: US 2011/0095271 A1
(43) Pub. Date: Apr. 28, 2011

(54) HYBRID ORGANIC LIGHT EMITTING DEVICE

(76) Inventors: Donal Donat Conor BRADLEY, Buckinghamshire (GB); Saif Ahmed HAQUE, London (GB)

(21) Appl. No.: 12/606,722

(22) Filed: Oct. 27, 2009

(51) Int. Cl. H01L 51/52; H01L 51/56

(52) U.S. Cl. 257/40; 438/46; 257/E51.022; 977/755

(57) ABSTRACT

A hybrid organic light-emitting device comprises an anode, a cathode, respective adjacent hole and electron transport layers and an emissive layer therebetween. The electron transport layer comprises a metal oxide as a result of which the cathode may be formed of a transparent conductive oxide and the anode of a high work function metal. The metal oxide used for the electron injection layer may be ZrO₂: thereby the device exhibits enhanced electron injection and allows the use of a variety of red, green and blue light-emitting polymers.

### TECHNOLOGY FIELD

This invention relates to a hybrid organic light-emitting device (OLED).

### BACKGROUND

Research in OLEDs is being carried out in a number of areas, for example application of such devices in solid-state lighting sources and display technologies and increasing interest is being shown in the internal structure and methodology of active layers within the device which can be shown to enhance device performance. OLEDs are now attracting considerable interest due to their potential applications in flexible displays and solid-state lighting.

A simple OLED is shown in FIG. 1 including a cathode 100 and an anode 102 between which an emissive layer 104 comprising a light-emitting polymer such as poly-para-(phenylene vinylene)(PPV) is sandwiched. In operation, the cathode injects electrons into the emissive layer and the anode injects holes into, that is to say, removes electrons from the emissive layer. During electrode injection the electrons enter the lowest unoccupied molecular orbital (LUMO) of the emissive layer and holes are injected into the highest occupied molecular orbital (HOMO) of the emissive layer. The electrons and holes are transported across the emissive layer and are recombined by transition of the electrons in the LUMO down to the holes in the HOMO. This exciton recombination generates a photon, providing the emissive properties of the device.

In order to overcome the potential difference between the Fermi energy of the cathode and anode and the LUMO and HOMO respectively of the emissive layer, a forward bias is applied across the device. In existing devices, to increase electron injection efficiency a low work function metal is selected for the cathode for example magnesium, barium, or calcium, hence providing a low level of electron dissociation. The anode is typically formed of indium tin oxide (ITO) whose conductivity allows addressing of the OLEDs to obtain pixellated emission, and whose transparency allows the photons to escape. The ITO is typically treated to ensure that hole injection matches electron injection as otherwise electrons will pass through the emissive layer into the anode, generating a leakage current. For example the ITO may be submitted to an ultraviolet-ozone cleaning treatment to lower its Fermi level. It is further known to dope the emissive layer to increase the proportion of photon inducing recombination.

Existing OLED developments are described in “Organic Light Emitting Devices—from Displays to Lighting” by Parthasarathy et al published in the Electro Chemical Society Interface, Summer 2003 Edition. A further improvement is described therein, allowing the decoupling of carrier injection and carrier transport roles in an OLED from the recombination role. In particular, as shown in FIG. 2, in addition to a cathode 200 and anode 202, an electron transport layer 204 is provided intermediate the cathode and the emissive layer 206 and a hole transport layer 208 is provided intermediate the anode and the emissive layer 206 providing a three layer structure. As a result the HOMO and LUMO respectively of the transport layers may be tailored without compromising the emissive properties of the emissive layer to improve injection and transport into the emissive layer.

In a further approach described in “Electroluminescence from Single Monolayers of Nanocrystals in Molecular Organic Devices” by Coe et al published in Nature, Volume 420, page 800, 19/26 Dec. 2002, a hybrid OLED is described including an inorganic emissive layer sandwiched between organic carrier transport layers.

A problem with existing approaches is that a low work function metal is required for the cathode, meaning that reactive metals are required. Typically, vacuum deposition is required for three layer devices, and deposition of an organic material onto the ITO anode is required, which may damage the ITO. Furthermore, treatment of the anode is required to ensure sufficient hole injection. Yet further, the efficiency/emissivity of the device is limited by the size of the interface between the transport layers and the emission layer.

Yet further, key challenges for the technological exploitation of OLEDs are the development of device structures that (i) exhibit improved environmental stability under operation, especially for flexible substrates and (ii) are able to emit with high efficiency at high luminance.

In terms of device stability, the use of highly reactive, low work-function metals such as barium or calcium as electron injecting layer (EIL) materials is a major concern for conventional OLED device architectures, since they easily degrade in the presence of oxygen and moisture. As such, developing more stable electrode systems and indeed new device architectures may be important for the realization of both stable and efficient OLEDs.

Another key problem with current OLEDs is that, to date only, devices employing the green emitting F8BT polymer have been reported. New device structures that enable efficient electroluminescence from a range of polymers are now needed to ensure availability of the red, green, blue and white light required for display and lighting applications.

### SUMMARY

Consistent with an embodiment of the invention, there is provided a hybrid organic light-emitting device comprising an anode, a cathode, a hole transport layer, an electron transport layer, and an emissive layer, wherein the electron transport layer comprises ZrO₂.

Features and advantages consistent with the invention will be set forth in part in the description which follows, and in part will be obvious from the description, or may be learned by practice of the invention. Such features and advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1 is a schematic device depiction of a simple single layer OLED;

FIG. 2 is a schematic diagram of a multi-layer OLED;

FIG. 3 is a schematic diagram showing an OLED consistent with the present invention;

FIG. 4 is a diagram showing energy levels of the various layers consistent with one arrangement of the present invention;

FIG. 5 is a diagram showing energy levels of the various layers consistent with another arrangement of the present invention;

FIG. 6 is a diagram showing energy levels of the various layers consistent with the present invention;

FIG. 7 is a schematic device depiction;

FIG. 8 shows current versus voltage (left) and luminance versus voltage (right) characteristics of a device consistent with the invention;

FIG. 9 shows current versus voltage (left) and luminance versus voltage (right) characteristics of an alternative device;

FIG. 10 presents a comparison of device efficiency for devices employing various materials;

FIG. 11 shows current efficiency versus luminance plots for devices employing different materials before and after annealing;

FIG. 12 shows the electroluminescence spectra of OLEDs consistent with the present invention; and

FIG. 13 shows the corresponding luminance versus voltage characteristics for OLEDs consistent with the present invention.

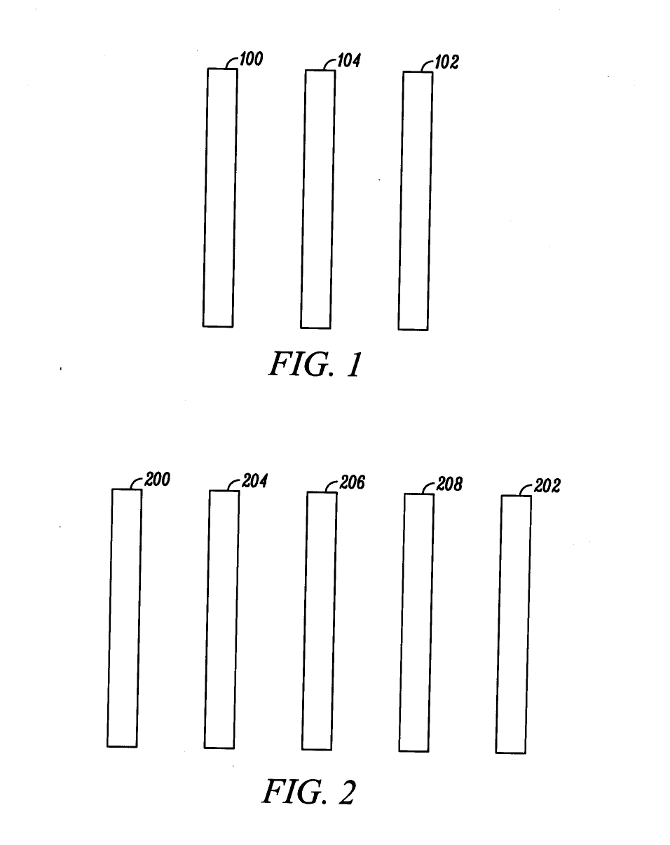

### DESCRIPTION OF THE EMBODIMENTS

In overview, consistent with the present invention there is provided a hybrid inorganic/organic light-emitting device or diode (LED) using a zirconium dioxide (ZᵣO₂) Electron Injection Layer (EIL). zirconium dioxide has surprisingly been found to be particularly suitable for use as the EIL.

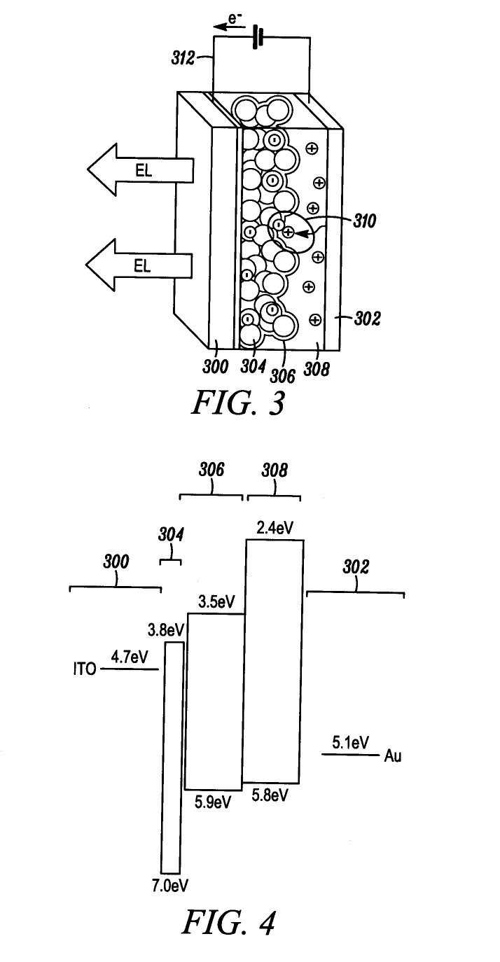

Referring to FIG. 3, the device comprises a cathode 300 and an anode 302 between which may be sandwiched a nanocomposite film comprising three structurally organised phases. The first phase may comprise an electron transport layer 304 adjacent the cathode and comprising a mesoporous nanocrystalline or planar zirconium dioxide (ZrO₂) film. The film may be coated with an emissive layer comprising a thin layer of an electroluminescent material shown generally at 306. An organic hole transporting polymer may comprise the hole transport layer 308 adjacent the anode and may interpenetrate into the ZrO₂ film pores (although interpenetration is not essential and in other embodiments the polymer may be planar). Hence, the device forms a hybrid OLED, with organic emissive and hole transporting layers and an inorganic electron transporting layer. A forward bias is applied at 312.

One recent approach is to use inorganic metal oxide films as charge injection layers. Metal oxides are particularly attractive in this role due to their mechanical and electrical robustness, low-cost, visible-light transparency, excellent environmental stability, good charge transport properties, and the controllability of their film morphology on nano to micro length scales. Metal oxide films have been recently employed as hole (HIL) and electron (EIL) injection layers in hybrid organic/inorganic light-emitting diodes (HyLEDs). The use of transparent metal oxide films as EIL is particularly attractive as it is then possible to use opaque high work function metals such as gold for hole injection (with or without a separate HIL), yielding more stable device architectures.

This may also allow the cathode to be formed of a transparent conducting oxide such as ITO whereas in prior art devices ITO has formed the anode.

Both titanium dioxide (TiO₂) and zinc oxide (ZnO) films have been recently investigated in polymer LEDs for use as EIL, and molybdenum trioxide (MoO₃) as a HIL. Typically, dense thin films have been used, but also nanostructured layers may be effective with the potential advantage of an enhanced injection current due to the convoluted contact area. Devices reaching luminance levels of ˜6,500 cd/m² have been reported for HyLEDs employing poly(9,9-dioctylfluorene-alt-benzothiadiazole) (F8BT) as an electroluminescent layer combined with ZnO and MoO₃ as EIL and HIL respectively. Whilst these studies demonstrate the attractiveness of this approach, further increases in luminance and efficiency are desirable.

For example, TiO₂ may be used as the electron transport layer. In addition to being a good electron transporting material TiO₂ conduction band energy level may be modulated by adjusting surface charge of TiO₂ film, providing a good energy level match with the adjacent cathode and emissive layers. In addition, the TiO₂ film serves the function of electron transport and injection into the emissive layer and provision of a desirable active layer morphology.

Moreover, it has been discovered that the device function is dominated by hole-injection and that electron injection from the metal oxide EIL into the lowest unoccupied molecular orbital (LUMO) of the semiconducting polymer may be a key limiting step. For example, the relatively deep conduction band level of TiO2 (˜3.8 eV below the vacuum level) compared to the (˜3.5 eV) LUMO of F8BT may reduce the efficiency of electron injection. Therefore, it is desirable to design alternative EIL that enable efficient electron injection into the polymer LUMO. Zirconium dioxide (ZᵣO₂) has surprisingly been found to be particularly suitable for use as the EIL. Previously, zirconia (ZrO₂) has not been considered in the literature for its electron conducting/semiconductor properties at room temperature as it is typically known and used based on its ionic conducting properties at high temperature. Indeed zirconium is typically used in ceramic form for example stabalised with yttria (Y₂O₃) for structural/refractory high temperature purposes.

As a result, electro-active structures may be developed such as shown in FIG. 3, combining the diversity of organic materials with the high performance electrical and structural properties of inorganic materials. The three component architecture may isolate the luminescence processes from the charge carrier transport, allowing each process to be optimised individually. In some instances, a two layer structure may be implemented where, for example, the hole transporting and emitter functions may be performed by the same material. Light-emitting devices based upon the multi-component hybrid nanocomposite films described consistent with the invention herein have been found to provide significant luminescence brightness. Furthermore, because of the reversal of operation the device structure may be less sensitive to the properties of the ITO substrate such that alternative, cheaper substrates such as fluorine-doped tin oxide coated glass layers may be used.

FIG. 4 is a diagram of the energy levels for an existing hybrid LED device having a structure: ITO/TiO₂/F8BT/PFO/AU as shown in FIG. 3. Electrons are injected from the ITO contact via the conduction band of the nanocrystalline TiO₂ into the LUMO of the F8BT material. Similarly, holes are injected from the gold contact via the PFO hole transport layer into the HOMO of the F8BT. By way of these two interfacial charge transfer reactions, F8BT excitons may be generated in the interface layer and radiatively recombined to emit light as shown in FIG. 3 at 310.

The Fermi level of the ITO is 4.7 eV, the LUMO of the TiO₂ is 3.8 eV, and the LUMO of the PFB8 is 3.5 eV. As can be seen, therefore, the energy levels are such that electron transport into the LUMO of the F8BT is permissible. The Fermi level of the gold contact is 5.1 eV, the HOMO of the PFO is 5.8 eV and the HOMO of the F8BT is 5.9 eV once again allowing hole injection transport into the emissive layer. At the emissive layer, electrons in the LUMO decay to the HOMO generating photons. Of course, the various material properties may be tuned to obtain different wavelengths; for example, the architecture described with reference to FIG. 4 provides red light.

In order for charge carrier injection to occur, an appropriate forward potential may be required to function. There is a 1 eV barrier for electron injection from the ITO into the conduction band of the TiO₂ and a further 0.3 eV barrier to electron injection from the transport level of TiO₂ into the LUMO of F8BT. In addition, there is a 0.7 eV barrier to hole injection from the gold into the PFO and a further 0.1 eV barrier from the PFO transport level into the HOMO of the F8BT. Of course it would be recognised that alternative material choice or optimisation may lead to a reduction in the barriers which in turn may lead to improvements in the voltage required to obtain the necessary forward bias, as well as the overall efficiency of the device.

The selection of metal oxides such as TiO₂, zinc oxide (ZnO) and tin oxide (SnO₂) is desirable in view of the good electron transporting properties as well as low cost, good stability, ease of fabrication and ease of morphology control at the nanocrystalline level. In addition, the use of a metal oxide may allow the reversal of the function of ITO such that it may be used as the cathode rather than the anode. Furthermore this means that a high work function metal such as gold or platinum or other material such as PEDOT-PSS poly(3,4-ethylene-dioxythiophene)-poly(styrene sulphonate) may be provided as hole transporting and injecting layer at the anode providing increased stability. Of course appropriate additives or interface layers may be introduced to enhance stability and performance of the TiO₂, although it is found that the metal oxide layer is inherently relatively insensitive to molecular oxygen induced photo degradation compared to organic polymer based devices.

In a previous HyLED device fabrication, a ˜150 nm thick nanocrystalline TiO₂ film is deposited on a plasma etched, patterned indium tin oxide (ITO) obtained for example from CRL apto substrate by spin coating from a colloidal solution of TiO₂ particles in water. After air drying, the electrode is fired for 30 mins at 450° C. The resulting film is then coated with an ultra-thin layer of F8BT electroluminescent polymer by immersion in a chlorobenzene solution containing 0.05M of the F8BT polymer for 1 hour, under nitrogen at 65° C. Following deposition, this layer is remarkably stable, with for example subsequent immersion of the film in neat chlorobenzene resulting in negligible desorption. The pores of the coated film are then filled by a PFO organic hole transporting material by spin coating from a chloroform solution containing 0.1M of the polymer, giving a structurally organized three component nanostructured film. To complete the device fabrication gold top electrodes are evaporated in 3×10⁻⁶ ton vacuum at a rate of 10 Ås⁻¹ (thickness ˜100 nm) through a shadow mask, which defines the device active area (0.02 cm²).

Further improvements in device function may result from the replacement of TiO₂ with ZrO₂, consistent with the present invention.

Accordingly, consistent with the present invention, a method of fabricating a hybrid organic light-emitting device may include depositing a layer of ZrO₂ over a transparent conducting oxide cathode such as a plasma etched, patterned ITO cathode. Then an emissive layer may be deposited over the ZrO₂ layer. The emissive layer may interpenetrate into the ZrO₂ layer. Next a hole transport layer may be deposited over the ZrO₂ layer. The hole transport layer may also interpenetrate into the emissive and ZrO₂ layers. After that, an anode layer may be deposited over the hole transport layer. The entire device may then be subjected to thermal annealing.

Solvents and materials used in the fabrication of metal oxide films consistent with the disclosed embodiments may be of a type similar to that which can be obtained from Sigma Aldrich, whilst Au wire can be obtained from Goodfellow. Light-emitting polymers used may be of a type such as that provided by the Sumitomo Chemical Company, Ltd. Compact zirconium dioxide layers may be deposited by spraying pyrolysis at 450° C. from a 0.033 M solution of zirconium acetylacetone in N,N-DMF as reported elsewhere. Compact TiO₂ layers may be fabricated from titanium acetylacetonate solution in ethanol, as previously described. The resulting thickness of both ZrO₂ and TiO₂ layers is approximately 40 nm. Electroluminescent polymer layers may be spin-coated from 10 g dm⁻³ chlorobenzene solutions. The polymers used are one of: red emitting Red F; green emitting poly(9,9 dioctylfluorene-altbenzothiadiazole) (F8BT) and Lumation™ 1300 series Green K (L-Green); and blue emitting poly(9,9-dioctylfluorene) (PFO) and a Lumation™ Blue (L-Blue). Device annealing is performed for 20 min at temperatures above the polymer melting point: 290° C. for F8BT and 250° C. for all the other polymers. More generally, the temperature may be selected to be close to but lower than the glass transition temperature of the active layer. MoO₃ (20 nm) and Au (100 nm) may be evaporated in vacuo (<5×10⁻⁶ mbar). Device characterization may be performed using a Keithley 2400 source combined with a Konica Minolta L100 luminance meter. Electroluminescence spectra may be measured using a Fluoromax spectrofluorimeter.

All polymers may be annealed above their melting point prior to vacuum deposition of the MoO₃ HIL and the Au electrode.

Other embodiments may employ Sumitomo Lumation™ series green (L-green) and blue (L-blue) light-emitting fluorenebased polymers together with Red F, poly(9,9-dioctylfluorene) (PFO) (blue emitting), and F8BT (green emitting) as the electroluminescent polymer (730). In these example embodiments, the Lumation polymers may be chosen as typical state-of-the-art OLED materials with PFO, F8BT, and Red F as representative earlier generation, more widely studied members of the same polyfluorene family.

As a result of the approaches described herein, a three component architecture may be achieved isolating the luminescence processes from electron and hole charge transport allowing the possibility of each component to be optimised separately. Use of a mesoporous nanocrystalline metal oxide film may enable the interfaces within the active device layer to be optimised at the nanometer length scale. As a result of the high interface area of the interpenetrating network junction with the electroluminescent layer (e.g. F8BT), higher coverage may be achieved, and high emission intensities may be available at low current densities, enhancing the power conversion efficiency and long term performance. These high surface area mesoporous films may be modified by the attachment of molecular dyes, polymers, or biomolecules. In the case of TiO₂ as EIL, the turn-on voltage is found to be reduced consistent with a reduction in the energy barrier to electron injection at the TiO₂/F8BT interface. Device efficiency is also observed believed to result from improved electron injection from the TiO₂ cathode into the LUMO of the F8BT. Furthermore the use of metal oxides allows the potential of room temperature fabrication, for example, by spin coating and avoids problems previously encountered in depositing potentially aggressive polymer materials onto the ITO substrate.

In operation, the zirconium based HyLED of the disclosed embodiments may have the following characteristics:

Zirconium dioxide (ZrO₂) has a conduction band onset (CB) of ˜3.0 eV below the vacuum level and a valence band (VB) onset of ˜8.7 eV (c.f. TiO₂ where CB ˜3.8 eV and VB ˜7 eV and ZnO where CB ˜4.0 eV and VB ˜7.1 eV). It is anticipated that the higher lying (closer to vacuum level) conduction band energy of ZrO₂ compared to TiO₂ and ZnO may enable more efficient electron injection into the LUMO of F8BT as well as other polymers typically used for organic LEDs: for reference we recall that calcium (Ca) has a work function of 2.9 eV and barium (Ba) 2.5 eV. Additionally, it is reasonable to expect the deep valence band energy to provide effective hole blocking, thereby reducing the hole leakage current and consequently enhancing the device efficiency. Hence, an improved HyLED performance may be obtained using ZrO₂ compared to previous findings and a device structure that may be used to achieve efficient electroluminescence from a range of red, green, and blue polymers.

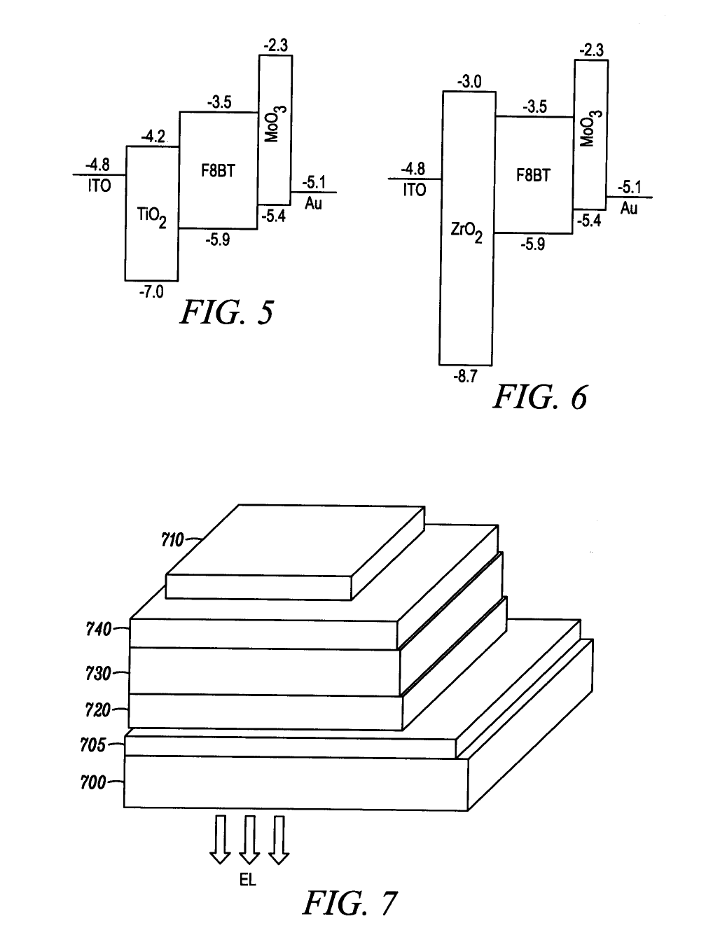

FIG. 7 shows the architecture of the devices in more detail. FIGS. 5 and 6 show the corresponding schematic energy level diagrams for ZrO₂ and (as a reference) TiO₂ based devices.

With reference to FIG. 7, a device consistent with the invention may have the following configuration:

glass substrate 700/indium tin oxide (ITO) cathode layer 705/metal oxide (ZrO₂) electron injection layer 720/electroluminescent polymer layer 730/metal oxide (MoO₃) hole injection layer 740/anode 710.

ITO and Au may be arranged as the cathode and anode conductors, respectively. MoO₃ may be arranged as a barrier-reducing hole injection layer HIL and electron-blocking layer.

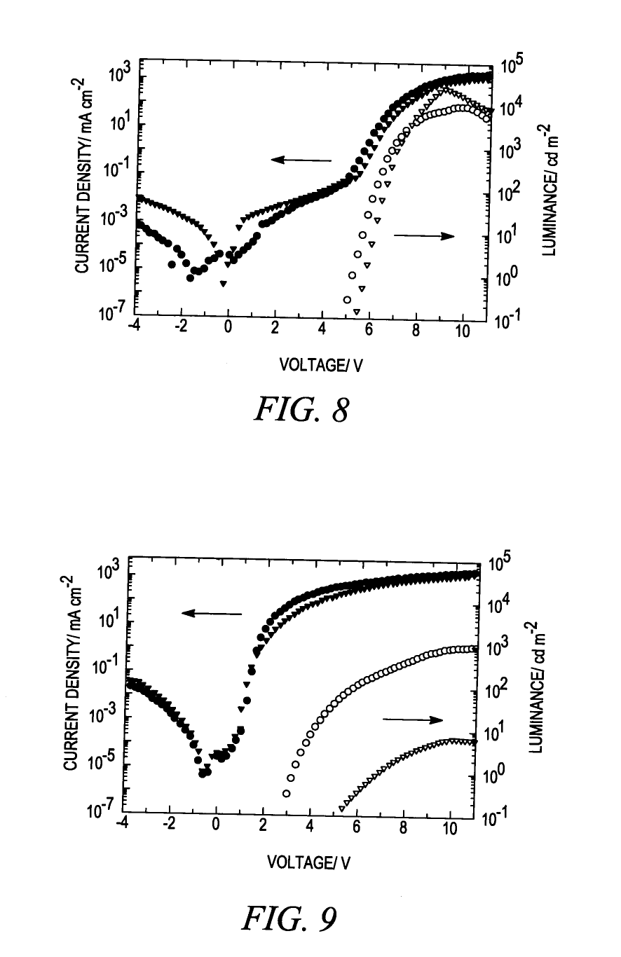

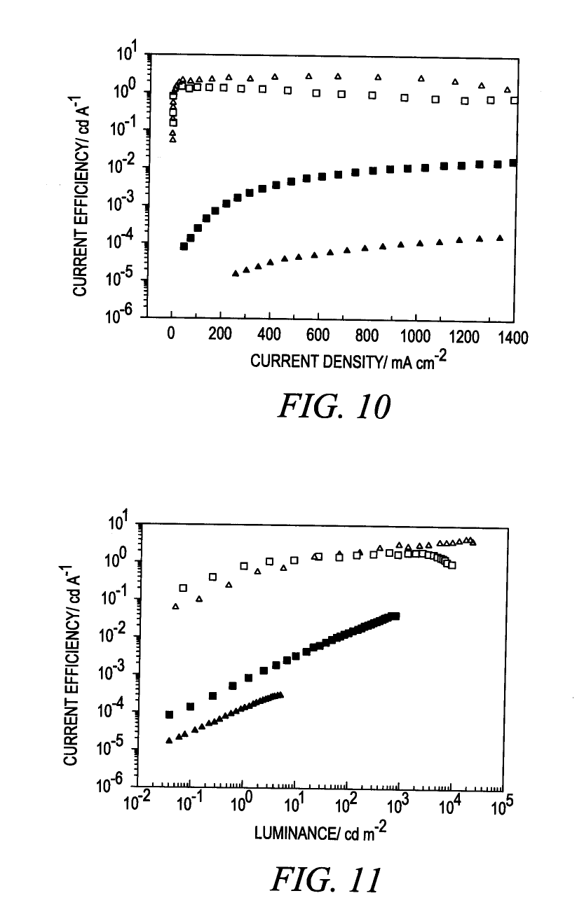

FIG. 8 shows current versus voltage (left ordinate) and luminance versus voltage (right ordinate) characteristics of ITO/ZrO₂/F8BT/MoO₃/Au devices with un-annealed polymer (circles) and polymer annealed above the melting point (triangles). FIG. 9 shows current versus voltage (left ordinate) and luminance versus voltage (right ordinate) characteristics of [ITO/TiO₂/F8BT/MoO₃/Au] devices with un-annealed polymer (circles) and polymer annealed above the melting point (triangles). FIG. 10 presents a comparison of HyLED efficiency for devices employing TiO₂ (full symbols) and ZrO₂ (open symbols) electron-injection layers before (squares) and after (triangles) annealing. FIG. 11 shows current efficiency versus luminance plots for devices employing TiO₂ (full symbols) and ZrO₂ (open symbols) electron-injection layers before (squares) and after (triangles) annealing. Annealing may result in an enhancement of current efficiency in the ZrO₂-based devices, especially at higher luminances.

Current density versus voltage (J-V) and luminance versus voltage (L-V) curves for a device containing ZrO₂ are presented in FIG. 8. The un-annealed [ITO/ZrO₂/F8BT/MoO₃/Au] diode exhibits a luminance of 9,920 cd/m2 at 9.8 V potential difference (Au positive with respect to ITO) with current density 1,485 mA/cm², corresponding to a current efficiency of ˜0.7 cd/A and a power efficiency of ˜0.2 lm/W. Annealing the F8BT polymer layer above its melting temperature (290° C.) may lead to a further increase in the maximum luminance to 25,970 cd/m² at 9 V, accompanied by a more than four-fold increase in efficiency to ˜3 cd/A (˜1 lm/W). The temperature annealing protocol performed here may result in little or no change in the absorption and luminescence properties of spin-coated F8BT films confirming that there may unlikely to be any consequent adverse effects on the polymer emission layer.

FIG. 9 shows the J-V and L-V characteristics for a control [ITO/TiO₂/F8BT/MoO₃/Au] device before and after thermal annealing. Before annealing the TiO₂ device reaches a luminance of ˜1,000 cd/m2 at 9V. Thermal annealing of this device type, however, may lead to a significant decrease in performance in strong contrast to the case for the ZrO₂ based devices. The maximum luminance falls from ˜1,000 cd/m² at 9 V (with efficiency 0.02 cd/A and 7.8×10-4 lm/W) to ˜10 cd/m² at 9 V (with efficiency 10-4 cd/A and 3.5×10⁻⁴ lm/W). The reduction in performance may occur because the improved physical contact between layers in the device coupled with the particular energy bands in TiO₂ may lead to increased exciton quenching and hence reduced emissivity.

The variation of the cd/A efficiency plotted as a function of current density and luminance is shown in FIGS. 10 and 11 respectively. Annealing the ZrO₂-based devices may result in an enhanced cd/A efficiency at all but the lowest current densities, namely for all luminances >50 cd/m².

Annealing may enhance operation of the ZrO₂ based device because improved physical contact may be achieved without increased quenching because of the higher conductive band edge.

In operation, the [ITO/TiO₂/F8BT/Mo03/Au] device of FIG. 7 operates as follows. Holes may be injected from the Au anode coated MoO₃ HIL into the highest occupied molecular orbital (HOMO) of F8BT and electrons may be injected from the TiO₂ EIL coated ITO cathode into the LUMO of F8BT. The use of MoO₃ may facilitate efficient hole-injection into F8BT. In contrast, electron injection from TiO₂ into F8BT in previous devices is not as efficient. The resulting imbalance in charge injection may lead to accumulation of holes at the TiO₂/F8BT interface, creating a large local electric field that promotes electron injection into the polymer, with subsequent exciton formation close to the TiO₂/polymer interface.

Possible reasons for poor electron injection from TiO₂ into F8BT may be: (i) a high energy barrier for injection from ITO into TiO₂, (ii) poor electron transport in the metal oxide, and (iii) an energy barrier between the conduction level of TiO₂ and the LUMO of F8BT. Another important factor limiting the performance of TiO₂ in HyLED structures may be (iv) the relatively poor hole blocking ability of titania. It may be reasonable to expect all of these four factors to play a role in the poor performance of previous devices. Studies have shown improved HyLED performance using ZnO in place of TiO₂ as EIL. Since TiO₂ and ZnO have very similar conduction band and valence band edge levels, this observation may most easily be rationalized in terms of the superior electron mobility of ZnO compared to TiO₂.

In the disclosed embodiments, the use of ZrO₂ as EIL may at least partially address limiting factors (iii) and (iv). As the conduction band level of ZrO₂ is situated higher than the F8BT LUMO (FIG. 6), this should lead to activation-less electron injection from the metal-oxide into the polymer. Additionally, the deeper valence band of ZrO₂ (8.7 eV) as compared to TiO₂ (7.0 eV) is believed to result in an even better hole blocking functionality. This is supported by comparison of the current densities for the TiO₂ and ZrO₂ devices (FIGS. 8 and 9) where an overall reduction in the current density for the ZrO₂ diode may be explained by a reduction in hole leakage current. The higher turn-on voltage of the ZrO₂ device (4.5 V) compared to the TiO₂ device (3 V) may be, moreover, consistent with the higher conduction band energy level of ZrO₂, which may create a larger electron injection barrier between ITO and the metal oxide.

Further optimization is clearly possible in the latter regard, for example, by insertion of one or more intermediate EILs with conduction band levels between those of ITO and ZrO₂.

As discussed above, it has been surprisingly found, as shown in FIGS. 8 to 11, that the performance of the [ITO/ZrO₂/F8BT/MoO₃/Au] device may improve upon thermal treatment whilst that of the [ITO/TiO₂/F8BT/MoO₃/Au] device may degrade upon the same treatment. The improved performance may be rationalized in terms of the formation of an improved contact between the polymer and the ZrO₂ EIL upon annealing as indicated above.

Moreover, n-type TiO₂ is known to quench F8BT excitons and is commonly used as an electron acceptor in both dye sensitized and hybrid inorganic/polymer solar cells due to its high electron affinity. In contrast, ZrO₂ may quench excitons in such devices, having an electron affinity that is ˜0.8 eV lower in energy. As such, thermal treatment of the TiO₂ device may lead to a decrease in device performance through enhanced exciton quenching. In contrast, the improved interfacial contact between the polymer and the ZrO₂ film upon thermal treatment may simply serve to improve charge injection from the metal oxide into the F8BT LUMO.

Furthermore, the ZrO₂ EIL HyLED device structure may be used to generate red, green and blue electroluminescence. This may be because of the more efficient electron injection and hole blocking capability of ZrO₂ resulting from the higher lying conduction band energy. This is particularly notable in relation to blue-emitting layers as the high conduction band level of ZrO₂ may allow injection of electrons into the emitter layer LUMO whilst blocking hole injection from the emitter layer HOMO as discussed above.

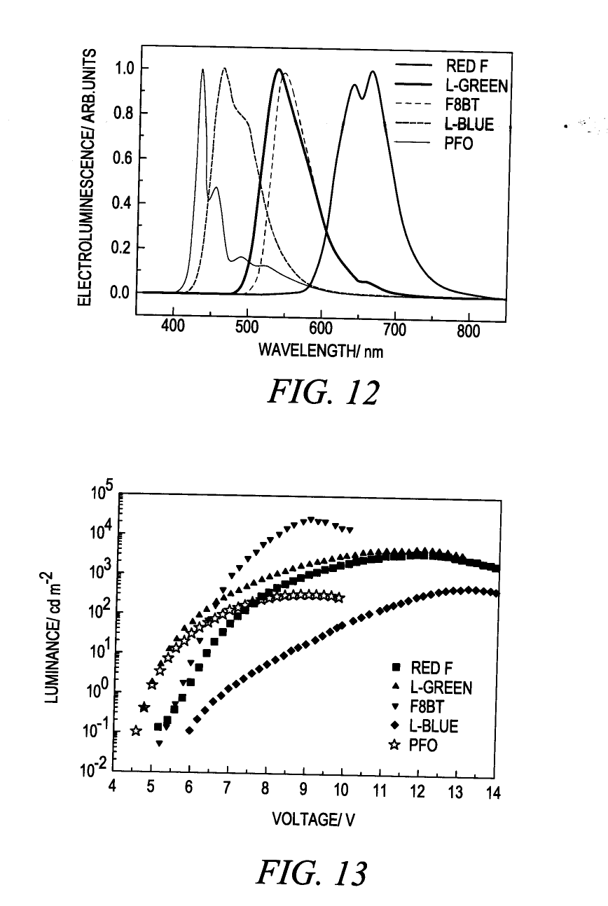

FIG. 12 shows the electroluminescence spectra of OLEDs with structure [ITO/ZrO₂/polymer/MoO₃/Au], in operation, using Red F, L-Green, and polyfluorene PFO emission materials. FIG. 13 shows the corresponding luminance versus voltage characteristics for the devices. L-Green and L-Blue are Lumation™ series proprietary light-emitting polymers from the Sumitomo Chemical Company, Ltd. Because a range of different emitter layers and types may be accommodated, a simple ZrO₂ fabrication system may be adopted for multiple device types, providing manufacturing benefits.

FIG. 13 shows the luminance versus voltage (L-V) characteristics for ZrO₂ based devices employing the five different polymers. Again, the improved performance is visible.

Table 1 shows device characteristics of OLEDs with structure [ITO/ZrO₂/polymer/MoO₃/Au] and [ITO/TiO₂/polymer/MoO₃/Au]. ZrO₂ EIL devices were annealed above the polymer melting temperatures, whereas TiO₂ EIL devices were not annealed.

TABLE 1

| | | Max. luminance | | Max. current efficiency | | Max. luminous efficacy | |
|---|---|---|---|---|---|---|---|
| Metal | | [cd m⁻²] | | [cd A⁻¹] | | [lm W⁻¹] | |
| oxide EIL | Polymer | (at Voltage [V]) | | (at luminance [cd m²]) | | (at luminance [cd m²]) | |
| ZrO₂ | Red F | 3,450 | (11.8) | 0.47 | (821.2) | 0.18 | (448.8) |
| | F8BT | 25,970 | (9) | 2.71 | (22870) | 1.02 | (5558) |
| | L-Green | 4,560 | (11.8) | 1.01 | (1003) | 0.41 | (481.8) |
| | L-Blue | 470 | (13.2) | 0.12 | (122) | 0.03 | (28.88 ) |
| | PFO | 309 | (9.2) | 0.03 | (59.1) | 0.015 | (59.1) |
| TiO₂ | Red F | 168 | (12.4) | 0.01 | (162.3) | 0.003 | (150.3) |
| | F8BT | 805 | (10.6) | 0.03 | (786.6) | 0.01 | (679.8) |
| | L-Green | 2.9 | (10.8) | 2 × 10⁻⁴ | (2.6) | 7 × 10⁻⁵ | (2.4) |
| | L-Blue | 5.1 | (14.8) | 7 × 10⁻⁴ | (5.0) | 2 × 10⁻⁴ | (4.7) |
| | PFO | 0.1 | (12.8) | 5 × 10⁻⁶ | (0.1) | 1 × 10⁻⁶ | (0.1) |

Device performance data are summarized in Table 1 above. All of the example embodiments exhibit bright electroluminescence characteristic of the polymer emission layer. In contrast, known devices using a TiO₂ EIL deliver considerably lower luminance values.

In summary, zirconium dioxide (ZrO₂) may be a good candidate for use as an EIL in hybrid organic/inorganic light-emitting diodes. Reported luminance values for F8BT devices are five times greater than for existing devices using TiO₂ or ZnO EILs, with the best performance achieved following annealing of the polymer layer. The improvement in device performance may be due to: (i) the better hole blocking ability of ZrO₂ associated with its deep valence band and (ii) more efficient electron injection into the F8BT LUMO associated with ZrO₂'s higher lying conduction band. Furthermore, the ZrO₂ EIL device architecture may be used to generate electroluminescence from a range of fluorene polymers spanning the visible spectrum from blue to green to red.

It will be appreciated that other appropriate cathode and anode material may be implemented, meeting the requirements set out above and similarly other appropriate metal oxides (for example a mesoporous nanocrystalline metal oxide) may be used as electrical transport layer. Similarly, other appropriate emissive layer and hole transport layer may be implemented and the various properties tuned to provide emitted light at an appropriate wavelength. Additional transport or emissive layers may be added as appropriate. Reference to layers throughout includes physically independent layers and interpenetrated layers as appropriate.

The foregoing description of possible implementations consistent with the present invention does not represent a comprehensive list of all such implementations or all variations of the implementations described. The description of only some implementations should not be construed as an intent to exclude other implementations. One of ordinary skill in the art will understand how to implement the invention in the appended claims in many other ways, using equivalents and alternatives that do not depart from the scope of the following claims.

What is claimed is:

1. A hybrid organic light-emitting device comprising:
an anode;
a cathode;
a hole transport layer;
an electron transport layer comprising ZrO₂; and
an emissive layer.

2. A device as claimed in claim 1, wherein the cathode comprises a transparent electrically conducting oxide.

3. A device as claimed in claim 2, wherein the transparent electrically conducting oxide comprises Indium Tin Oxide.

4. A device as claimed in claim 1, wherein the anode comprises a high work function metal.

5. A device as claimed in claim 4, wherein the high work function metal comprises at least one of gold, platinum, or PEDOT-PSS.

6. A device as claimed in claim 1, wherein the electron transport layer comprises a mesoporous layer.

7. A device as claimed in claim 1, wherein the electron transport layer comprises a nanocrystalline structure.

8. A device as claimed in claim 1, wherein one of the hole and electron transport layers also acts as emissive layer.

9. A device as claimed in claim 1, wherein the hole transport layer comprises MoO₃.

10. A device as claimed in claim 1, wherein the emissive layer comprises one of Red F, F8BT, PFO, L-blue, and L-green.

11. A method of fabricating a hybrid organic light-emitting device comprising:
depositing a layer of ZrO₂ over a transparent conducting oxide cathode;
depositing an emissive layer over the ZrO₂ layer;
depositing a hole transport layer over the emissive layer;
forming an anode over the hole transport layer; and
annealing the device.

12. A method as claimed in claim 11, wherein the ZrO₂ is one of a mesoporous or a planar film.

13. A method as claimed in claim 11, wherein the emissive layer is deposited on the ZrO₂ layer.

14. A method as claimed in claim 11, wherein the emissive layer is deposited to interpenetrate into the ZrO₂ layer.

15. A method as claimed in claim 11, wherein the hole transport layer is deposited on the emissive layer.

16. A method as claimed in claim 11, wherein the hole transport layer is deposited to interpenetrate into the emissive and ZrO₂ layers.
